(19) United States
(12) Patent Application Publication
(10) Pub. No.: US 2010/0116057 A1
(43) Pub. Date: May 13, 2010

(54) MEMS SENSOR AND METHOD OF MANUFACTURING THE SAME

(75) Inventor: Goro Nakatani, Kyoto (JP)

Correspondence Address: RABIN & Berdo, PC, 1101 14TH STREET, NW, SUITE 500, WASHINGTON, DC, 20005, US

(73) Assignee: ROHM CO., LTD., Kyoto-shi, Kyoto (JP)

(21) Appl. No.: 12/451,497

(22) PCT Filed: May 16, 2008
(86) PCT No.: PCT/JP2008/059078

§ 371 Date: Nov. 16, 2009

(30) Foreign Application Priority Data
May 17, 2007 (JP) 2007-131831

(51) Int. Cl. G01P 15/12; H05K 3/02

(52) U.S. Cl. 73/514.33; 29/847

(57) ABSTRACT

An MEMS (Micro Electro Mechanical Systems) sensor includes a base layer and a deformation portion provided on the base layer at an interval from the base layer and deformed by external force. The deformation portion is made of an organic material.

### TECHNICAL FIELD

The present invention relates to a sensor manufactured by a MEMS (Micro Electro Mechanical Systems) technique and a method of manufacturing the same.

### PRIOR ART

A MEMS sensor, having been recently loaded on a portable telephone, is increasingly watched with interest. For example, a piezoresistive acceleration sensor for detecting the acceleration of a substance is known as a typical MEMS sensor.

FIG. 15 is a schematic perspective view showing the structure of a conventional piezoresistive acceleration sensor in a partially fragmented manner.

A conventional MEMS sensor 101 includes a frame 102, a weight 103 and four beams 104.

The frame 102 is in the form of a quadrangular ring (a frame) in plan view, and has a thickness of about 400 μm, for example.

The weight 103 is arranged on a region surrounded by the frame 102 at an interval from the frame 102. The weight 103 is composed of a central columnar portion 105 in the form of a quadrangular column and four peripheral columnar portions 106 in the form of quadrangular columns provided on the periphery thereof. Each of the central columnar portion 105 and the peripheral columnar portions 106 has a thickness (height) identical to that of the frame 102. The central columnar portion 105 is arranged on a central portion of the region surrounded by the frame 102, so that the outer peripheral edges thereof are parallel to the inner peripheral edges (the inner surfaces) of the frame 102 in plan view. The peripheral columnar portions 106 are arranged one by one on extensions of respective diagonal lines toward both sides on the upper surface of the central columnar portion 105. Single corners of the side surfaces of the peripheral columnar portions 106 are connected to the corners of the side surfaces of the central columnar portion 105 respectively. Thus, the central columnar portion 105 and the four peripheral columnar portions 106 integrally constitute the weight 103 having the same thickness as the frame 102.

Each beam 104 extends between each pair of peripheral columnar portions 106 adjacent to each other, parallelly to the side surfaces of the peripheral columnar portions 106 at intervals. An end of the beam 104 is connected to the frame 102, while another end thereof is connected to the central columnar portion 105. The beam 104 has a thickness of about 7 μm, for example, to be twistable and deflectable due to the thickness. Thus, the four beams 104 support the weight 103 to be vibratile with respect to the frame 102.

A plurality of piezoresistive elements are arranged on the four beams 104, although the same are not shown.

When acceleration acts on the MEMS sensor 101 and the weight 103 vibrates, the beams 104 are distorted. Due to the distortion of the beams 104, stress acts on the piezoresistive elements on the beams 104, to change the resistivity of the piezoresistive elements. When the change of the resistivity of each piezoresistive element is extracted as a signal, therefore, the acceleration acting on the MEMS sensor 101 (the weight 103) can be detected on the basis of the signal.

The MEMS sensor 101 is manufactured by employing a substrate having a multilayer structure of a silicon back layer having a thickness of 400 μm, a silicon oxide layer having a thickness of 1 μm and a silicon front layer having a thickness of 7 μm. In the steps of manufacturing the same, the silicon front layer is first selectively etched through the silicon oxide layer serving as an etching stopper, whereby a front-side groove surrounding a portion for forming each peripheral columnar portion 106 is formed in the silicon front layer. Then, the silicon back layer is selectively etched through the silicon oxide layer serving as an etching stopper, whereby a back-side groove opposed to a portion for forming each beam 104 and the front-side groove is formed in the silicon back layer. A portion of the silicon oxide layer exposed through the back-side groove is etched, whereby the beam 104 consisting of the silicon front layer is formed while the frame 102 and the weight 103 consisting of the silicon back layer, the silicon oxide layer and the silicon front layer are formed. Consequently, the MEMS sensor 101 is obtained.
Patent Document 1: Japanese Unexamined Patent Publication No. 2005-351716

### DISCLOSURE OF THE INVENTION

### Problems to be Solved

Thus, in order to obtain the MEMS sensor 101, the silicon back layer and the silicon oxide layer must be removed from portions opposed to the beams 104 while leaving the same in the portions for forming the frame 102 and the weight 103. The portions of the silicon back layer and the silicon oxide layer opposed to the beams 104 are not exposed from the front-side grooves formed in the silicon front layer, and hence removal of the portions can be attained only by the etching from the side of the silicon back layer. Therefore, the substrate must be etched from both of the sides of the silicon front layer and the silicon back layer, and it takes time to manufacture the MEMS sensor 101.

Accordingly, an object of the present invention is to provide an easily manufacturable MEMS sensor and a method of manufacturing the same.

### Solutions to the Problems

A MEMS sensor according to an aspect of the present invention includes a base layer, and a deformation portion provided on the base layer at an interval from the base layer and deformed by external force, while the deformation portion is made of an organic material.

The MEMS sensor is obtained by stacking a sacrificial layer and an organic material layer in this order on the base layer, forming a through-hole in the organic material layer and etching (isotropically etching) the sacrificial layer through the through-hole, for example.

Therefore, the MEMS sensor can be easily manufactured without etching the base layer.

The base layer may not be etched, whereby the MEMS sensor can be loaded on a semiconductor substrate provided with elements such as CMOS devices. In other words, the MEMS sensor can be provided on a common semiconductor substrate mixedly with elements such as CMOS devices.

The MEMS sensor may include a weight provided on a surface of the deformation portion opposed to the base layer.

The MEMS sensor may further include a frame supporting the deformation portion on the periphery of the weight, a resistive conductor arranged on the deformation portion, and a wire arranged on the deformation portion and connected to the resistive conductor. In other words, the MEMS sensor may be a piezoresistive acceleration sensor including a deformable beam made of an organic material, a weight made of the organic material and integrally formed with the beam, a frame supporting the beam on the periphery of the weight, a resistive conductor arranged on the beam, and a wire arranged on the beam and connected to the resistive conductor.

The MEMS sensor having this structure can be obtained by a manufacturing method including the steps of forming a sacrificial layer on a base layer, forming a recess in the surface of the sacrificial layer, forming an organic material layer to fill up the recess and to cover the surface of the sacrificial layer, forming a wire on the organic material layer, forming a resistive conductor connected with the wire on the organic material layer, forming a groove along the periphery of the recess in plan view by etching the organic material layer from the surface side of the organic material layer, and forming a beam and a weight consisting of the organic material layer by etching the sacrificial layer through the groove. According to the manufacturing method, the MEMS sensor can be easily manufactured without etching the base layer.

The weight may be made of the organic material, and may be integrally formed with the deformation portion.

The MEMS sensor may include a first electrode provided on a surface of the base layer opposed to the deformation portion, and a second electrode provided on a surface of the deformation portion opposed to the base layer and opposed to the first electrode at an interval.

The first electrode and the second electrode constitute a capacitor whose capacitance changes in response to a change in the interval therebetween. When a physical quantity (acceleration, for example) in a prescribed direction is caused in the MEMS sensor (a substance loaded with the MEMS sensor) or a physical quantity (a pressure such as a sound pressure, for example) in a prescribed direction acts on the MEMS sensor, the deformation portion is deformed and the second electrode is thereby displaced, the interval between the first electrode and the second electrode changes. Thus, the capacitance of the capacitor constituted of the first electrode and the second electrode changes, and hence the physical quantity in the prescribed direction can be detected on the basis of the change of the capacitance. Therefore, the MEMS sensor including the first electrode and the second electrode can be employed as a capacitance type acceleration sensor, and can be employed as a microphone.

The MEMS sensor including the first electrode and the second electrode can be obtained by a manufacturing method including the steps of forming a first electrode made of a first conductive material on a base layer, forming a sacrificial layer made of a material different from the first conductive material on the first electrode, forming a second electrode made of a second conductive material identical to or different from the first conductive material on the sacrificial layer, forming an organic material layer made of an organic material on the second electrode, forming a through-hole penetrating the organic material layer and the second electrode in the stacking direction thereof, and forming a space between the first electrode layer and the second electrode by etching the sacrificial layer through the through-hole. According to the manufacturing method, the MEMS sensor can be easily manufactured without etching the base layer.

The MEMS sensor including the first electrode and the second electrode may include a protrusion provided on the surface of the deformation portion opposed to the base layer.

The protrusion may be made of the organic material, and may be integrally formed with the deformation portion.

The organic material may be polyimide.

The foregoing and other objects, features and effects of the present invention will become more apparent from the following detailed description of the embodiments with reference to the attached drawings.

### BRIEF DESCRIPTION OF THE DRAWINGS

FIG. 1A is a schematic plan view of a MEMS sensor according to an embodiment of the present invention.

FIG. 1B is a schematic sectional view taken along a line B-B shown in FIG. 1A.

FIG. 2A is a schematic plan view in the process of manufacturing the MEMS sensor shown in FIG. 1.

FIG. 2B is a schematic sectional view taken along a line B-B shown in FIG. 2A.

FIG. 3A is a schematic plan view showing a step subsequent to FIG. 2A.

FIG. 3B is a schematic sectional view taken along a line B-B shown in FIG. 3A.

FIG. 4A A schematic plan view showing a step subsequent to FIG. 3.

FIG. 4B is a schematic sectional view taken along a line B-B shown in FIG. 4A.

FIG. 5 A schematic sectional view showing a step subsequent to FIG. 4.

FIG. 6 A schematic sectional view showing a step subsequent to FIG. 5.

FIG. 7A A schematic plan view showing a step subsequent to FIG. 6.

FIG. 7B is a schematic sectional view taken along a line B-B shown in FIG. 7A.

FIG. 8 is a schematic sectional view of a MEMS sensor according to another embodiment of the present invention.

FIG. 9 is a schematic sectional view in the process of manufacturing the MEMS sensor shown in FIG. 8.

FIG. 10 is a schematic sectional view showing a step subsequent to FIG. 9.

FIG. 11 is a schematic sectional view showing a step subsequent to FIG. 10.

FIG. 12 is a schematic sectional view showing a step subsequent to FIG. 11.

FIG. 13 is a schematic sectional view showing a step subsequent to FIG. 12.

FIG. 14 is a schematic sectional view showing a step subsequent to FIG. 13.

FIG. 15 A schematic perspective view showing the structure of a conventional MEMS sensor in a partially fragmented manner.

### DESCRIPTION OF THE REFERENCE NUMERALS

1 MEMS sensor

2 base layer

3 frame

4 beam

5 weight

6 resistive conductor

7 wire

8 supporting portion

9 beam body portion

21 SiN layer

22 recess

23 organic material layer

26 groove

51 MEMS sensor

52 base layer

53 first electrode

54 diaphragm

55 protrusion

56 second electrode

### BEST MODE FOR CARRYING OUT THE INVENTION

Embodiments of the present invention are now described with reference to the attached drawings.

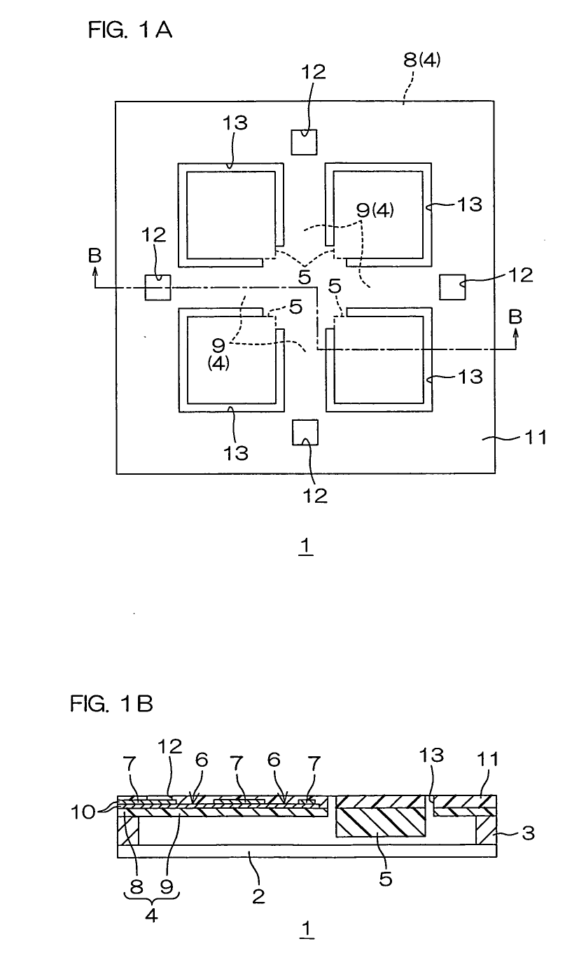

FIG. 1A is a schematic plan view of a MEMS sensor according to an embodiment of the present invention, and FIG. 1B is a schematic sectional view of the MEMS sensor taken along a line B-B shown in FIG. 1A.

A MEMS sensor 1 is a piezoresistive acceleration sensor, and includes abase layer 2, a frame 3, a beam 4, weights 5, resistive conductors 6 and wires 7.

The base layer 2 is made of SiO₂ (silicon oxide). The base layer 2 is in the form of a quadrangle in plan view, and has a thickness of 0.1 to 3 μm.

The frame 3, the beam 4, the weights 5, the resistive conductors 6 and the wires 7 are provided on the base layer 2.

The frame 3 is made of SiN (silicon nitride). The frame 3 is in the form of a quadrangular ring (a frame) along the peripheral edges of the base layer 2 in plan view, and has a thickness of 1 to 10 μm.

The beam 4 and the weights 5 are made of an organic material (polyimide, for example), and integrally formed.

The beam 4 integrally includes a supporting portion 8 in the form of a quadrangular ring in plan view supported by the frame 3 and a beam body portion 9 in the form of a cross in plan view supported by the supporting portion 8. The forward ends of the beam body portion 9 are connected to the centers of the sides of the supporting portion 8 respectively. Thus, the beam 4 has four quadrangular openings partitioned by the supporting portion 8 and the beam body portion 9. The beam 4 has a thickness of 1 to 10 μm, so that the beam body portion 9 is twistable and deflectable due to the thickness.

Each weight 5 is arranged in each opening of the beam 4. The weight 5 is in the form of a generally quadrangular column, whose upper surface is flush with the upper surface of the beam 4, having a thickness (height) of 1 to 10 μm. The side surfaces of the weight 5 are parallel to the peripheral edges of the opening with clearances. One of four corners formed by the side surfaces of the weight 5 is connected to the central portion of the beam body portion 9 of the beam 4. Thus, the weight 5 is supported by the beam 4 (the beam body portion 9) in a state not in contact with the base layer 2 and the frame 3.

A laminate 10 of a Ti (titanium) layer, a TiN (titanium nitride) layer and an Al (aluminum) —Cu (copper) alloy layer is stacked on the beam 4. The laminate 10 has end portions arranged on the supporting portion 8, extends along the beam body portion 9, and is in the form of a cross in plan view as a whole. The lowermost Ti layer and the TiN layer provided thereon are continuously formed. On the other hand, the uppermost Al—Cu alloy layer is broken on twelve portions, for example, to be intermittently formed. Thus, the Ti layer and the TiN layer are partially exposed on the broken portions (removed portions) of the Al—Cu alloy layer so that the exposed portions form the resistive conductors 6, while the Al—Cu alloy layer forms the wires 7 connected to the resistive conductors 6.

The outermost surface of the MEMS sensor 1 is covered with a protective film 11 made of polyimide, for example. The protective film 11 is provided with pad openings 12 exposing end portions of the wires 7 formed along the cross in plan view as pads for external connection respectively. The protective film 11 is also provided with grooves 13 communicating with the clearances between the beam 4 and the weights 5.

When acceleration acts on the MEMS sensor 1 and the weights 5 vibrate, distortion (twist and/or deflection) is caused on the beam body portion 9 of the beam 4. The resistive conductors 6 on the beam body portion 9 are expanded/contracted due to the distortion of the beam body portion 9, and the resistance values of the resistive conductors 6 change. The changes of the resistance values are extracted as signals through the pads, so that the directions (triaxial directions) and the magnitudes of the acceleration acting on the weights 5 (the MEMS sensor 1) can be detected on the basis of the signals.

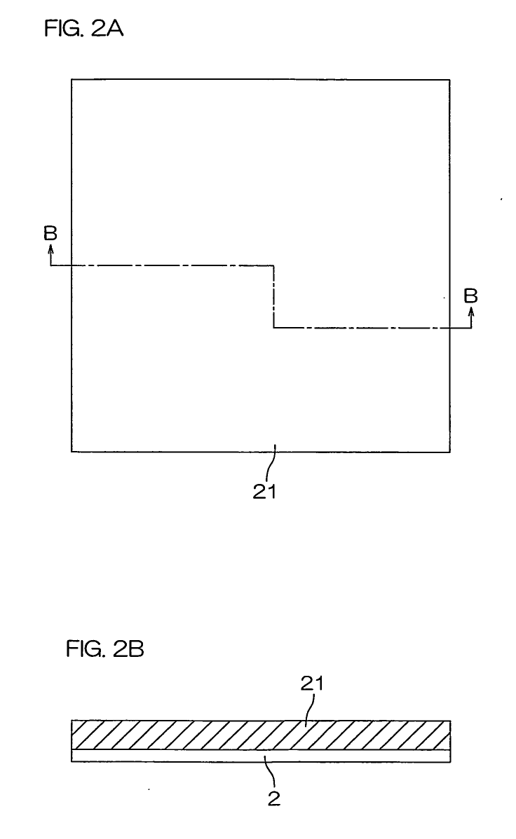

FIGS. 2A to 7B are diagrams for illustrating a method of manufacturing the MEMS sensor shown in FIGS. 1A and 1B.

First, an SiN layer 21 as a sacrificial layer made of the material for the frame 3 is formed on the base layer 2 by P-CVD (Plasma Chemical Vapor Deposition), as shown in FIGS. 2A and 2B. FIG. 2A is a schematic plan view showing the state where the SiN layer 21 is formed on the base layer 2, and FIG. 2B is a schematic sectional view of the structure shown in FIG. 2A taken along a line B-B.

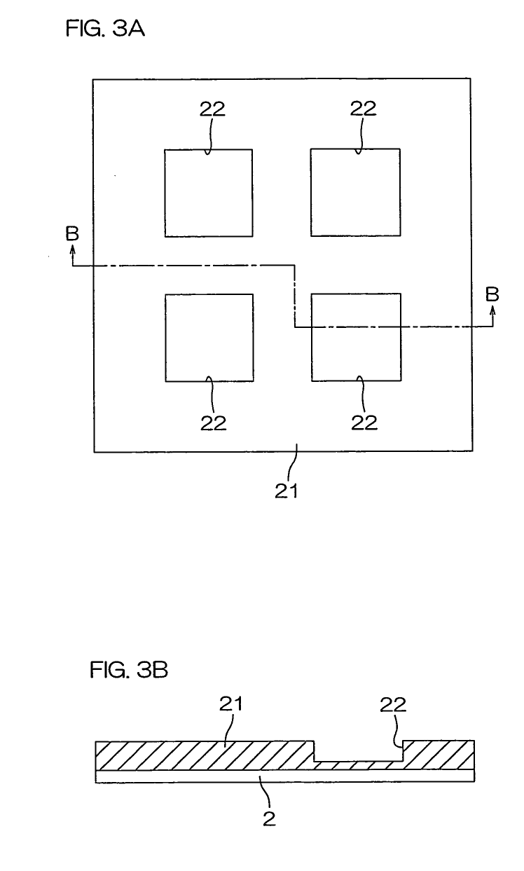

Then, a resist film having openings in portions corresponding to portions for forming the weights 5 respectively is formed on the SiN layer 21. Then, the SiN layer 21 is etched by RIE (Reactive Ion Etching) through the resist film serving as a mask. Consequently, four recesses 22 are formed in the surface of the SiN layer 21, as shown in FIGS. 3A and 3B. FIG. 3A is a schematic plan view showing the state where the recesses 22 are formed in the SiN layer 21, and FIG. 3B is a schematic sectional view of the structure shown in FIG. 3A taken along a line B-B.

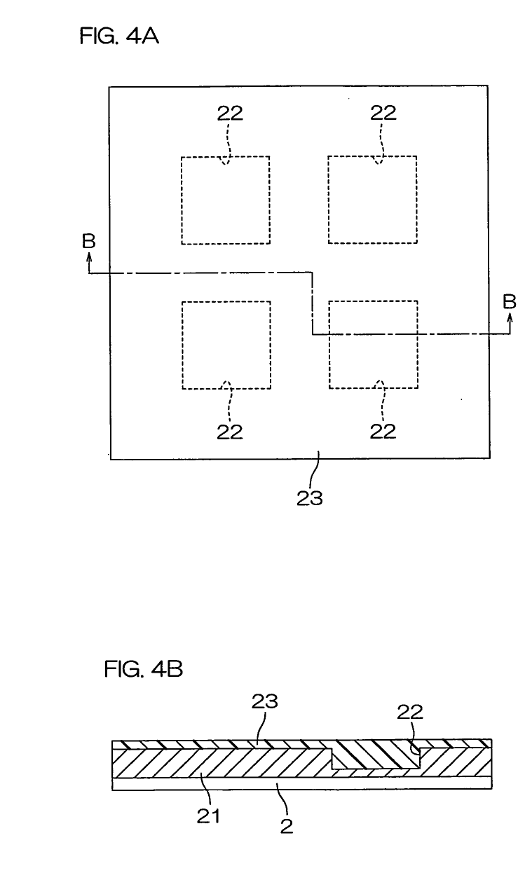

Thereafter the organic material (polyimide, for example) which is the material for the beam 4 and the weights 5 is applied onto the overall region of the SiN layer 21 having the recesses 22, whereby an organic material layer 23 made of the organic material is formed, as shown in FIGS. 4A and 4B. The organic material layer 23 fills up the recesses 22 and covers the overall region of the surface of the SiN layer 21, while the surface thereof is generally planar. FIG. 4A is a schematic plan view showing the state where the organic material layer 23 is formed on the SiN layer 21, and FIG. 4B is a schematic sectional view of the structure shown in FIG. 4A taken along a line B-B.

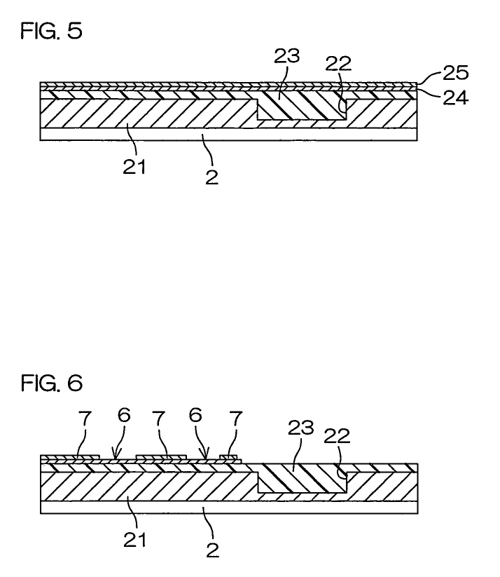

Then, a Ti layer/TiN layer 24 and an Al—Cu alloy layer 25 are formed on the organic material layer 23 in this order by sputtering, as shown in FIG. 5.

Thereafter the Ti layer/TiN layer 24 and the Al—Cu alloy layer 25 are patterned, whereby the resistive conductors 6 and the wires 7 are formed, as shown in FIG. 6.

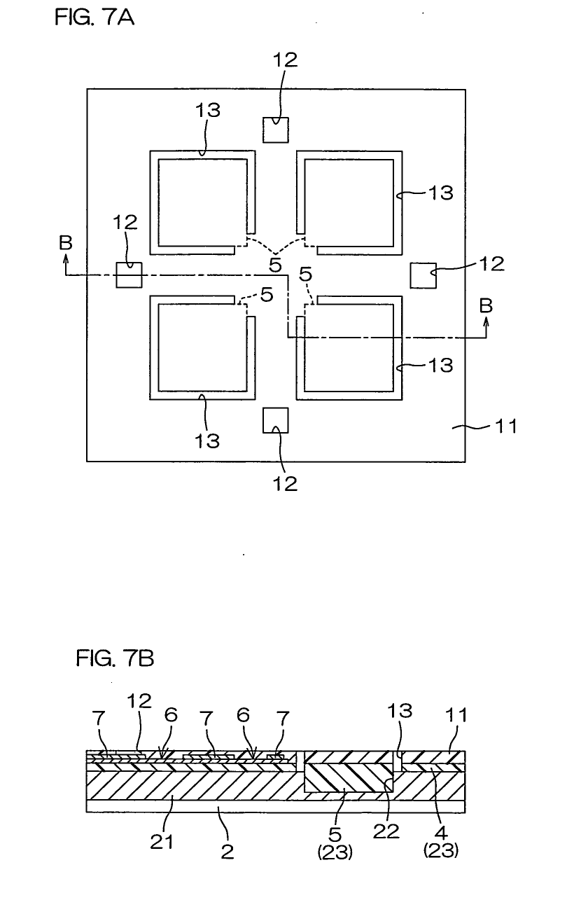

Then, the material for the protective film 11 is applied onto the organic material layer 23 provided with the resistive conductors 6 and the wires 7, as shown in FIGS. 7A and 7B. Then, the layer made of the material for the protective film 11 is partially removed, whereby the pad openings 12 are formed. Further, the layer made of the material for the protective film 11 and the organic material layer 23 are partially removed, whereby the grooves 13 corresponding to the clearances between the beam 4 and the weights 5 are formed to be along the outer peripheries of the recesses 22 in plan view respectively. Thus, the organic material layer 23 forms the beam 4 and the weights 5. The grooves 13 are so formed that the surface of the SiN layer 21 is partially exposed through the grooves 13.

Thereafter portions of the SiN layer 21 located under the beam 4 and the weights 5 are removed by CDE (Chemical Dry Etching) from the side of the protective film 11 through the grooves 13. The etching of the SiN layer 21 by CDE is continued until the portions of the SiN layer 21 located under the weights 5 are entirely removed. At this time, the base layer 2 made of SiO₂, having an extremely small etching rate as compared with the SiN layer 21, functions as an etching stopper layer. Consequently, the SiN layer 21 is patterned into the frame 3, and the MEMS sensor 1 having the structure shown in FIG. 1 is obtained.

As hereinabove described, the recesses 22 are formed in the surface of the SiN layer 21, and the organic material layer 23 is thereafter formed on the SiN layer 21 to fill up the recesses 22 and to cover the surface of the SiN layer 21. Then, the resistive conductors 6 and the wires 7 are formed on the organic material layer 23. Further, the organic material layer 23 is etched from the surface side of the organic material layer 23 along the outer peripheries of the recesses 22 in plan view. Thus, the beam 4 and the weights 5 consisting of the organic material layer 23 are formed. Then, the SiN layer 21 is etched through the grooves 13 formed by the etching, whereby the frame 3 supporting the beam 4 on the peripheries of the weights 5 is formed.

Thus, the MEMS sensor 1 having the structure shown in FIG. 1 can be easily manufactured without etching the base layer 2.

The base layer 2 may not be etched, whereby the MEMS sensor 1 can be loaded on a semiconductor substrate provided with elements such as CMOS devices. In other words, the MEMS sensor 1 can be provided on a common semiconductor substrate mixedly with elements such as CMOS devices.

While the case where SiO₂ is employed as the material for the base layer 2 and SiN is employed as the material for the frame 3 has been described by way of example, SiN may be employed as the material for the base layer 2, and SiO₂ may be employed as the material for the frame 3. In this case, etching of an SiO₂ layer made of the material for the frame 3 can be achieved by wet etching employing hydrofluoric acid, for example.

The material for the base layer 2 may simply be prepared from a material increasing a selection ratio in etching (etching for forming the frame 3) of the layer made of the material for the frame 3, and Al can be illustrated when the frame 3 is made of SiO₂.

When the substrate loaded with the MEMS sensor 1 has a layer employing the material increasing the selection ratio in the etching of the layer made of the material for the frame 3 on the outermost layer (the layer in contact with the MEMS sensor 1), the base layer 2 can be omitted.

When the quantity of the etching for forming the frame 3 is controlled by time, the base layer 2 and the frame 3 may be made of the same material (SiO₂, for example).

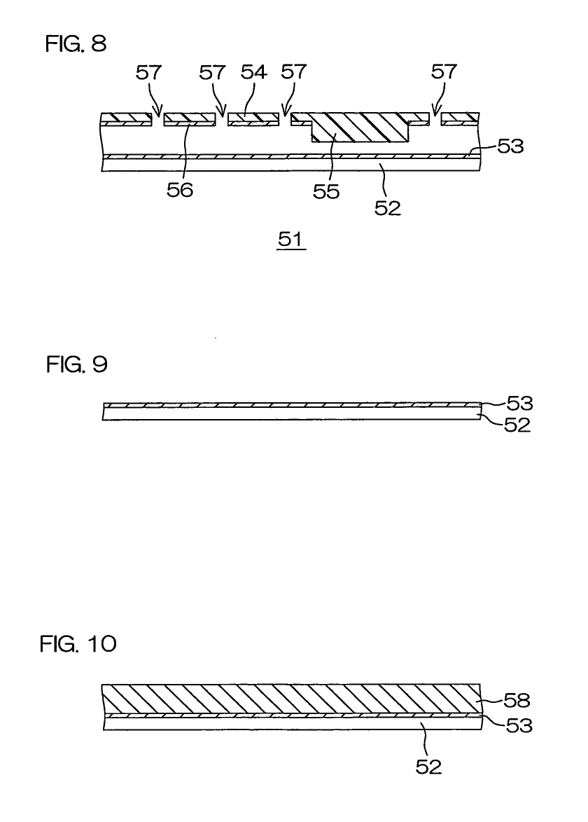

FIG. 8 is a schematic sectional view of a MEMS sensor according to another embodiment of the present invention.

A MEMS sensor 51 is a microphone, and includes a base layer 52, a first electrode 53, a diaphragm 54, a protrusion 55 and a second electrode 56.

The base layer 52 is made of SiO₂ (silicon oxide). The base layer 52 is in the form of a quadrangle in plan view, and has a thickness of 0.1 to 3 μm.

The first electrode 53, the diaphragm 54, the protrusion 55 and the second electrode 56 are provided on the base layer 52.

The first electrode 53 is made of Al (aluminum). The base layer 52 is formed on the surface of the base layer 52 as a film having a thickness of 0.3 to 2.0 μm.

The diaphragm 54 and the protrusion 55 are made of an organic material (polyimide, for example), and integrally formed.

The diaphragm 54 is in the form of a film having a thickness of 0.3 to 2.0 μm, and the peripheral edge portions thereof are supported by an unshown supporting portion. A space of 1 to 5 μm is formed between the diaphragm 54 and the base layer 52. A central portion of the diaphragm 54 is vibratile (deformable) in the direction opposed to the base layer 52.

The protrusion 55 is provided on the surface (the lower surface) of the diaphragm 54 opposed to the base layer 52. The protrusion 55 is in the form of a generally quadrangular column having a thickness (height) of 1 to 20 μm, and a space of 1 to 10 μm is formed between the same and the base layer 52. The protrusion 55 is so provided that the second electrode 56 described below can be prevented from coming into contact with the first electrode 53 in vibration of the diaphragm 54. In other words, the protrusion 55 functions as a stopper regulating the quantity of vibration of the diaphragm 54. Only one protrusion 55 may be formed, or a plurality of protrusions 55 may be formed.

The second electrode 56 is made of Al (aluminum). The second electrode 56 is formed on the surface of the diaphragm 54 opposed to the base layer 52 as a film having a thickness of 0.3 to 2.0 μm. Thus, the second electrode 56 is opposed to the first electrode 53 at an interval, and constitutes a capacitor whose capacitance changes in response to the interval.

When a sound pressure is input in the MEMS sensor 51, the diaphragm 54 vibrates, whereby the second electrode 56 is displaced. The interval between the first electrode 53 and the second electrode 56 changes due to the displacement of the second electrode 56, and the capacitance of the capacitor constituted of the first electrode 53 and the second electrode 56 changes. Therefore, the sound pressure input in the MEMS sensor 51 can be detected by extracting the change of the capacitance as a sound output signal.

A plurality of through-holes 57 are formed in the diaphragm 54 and the second electrode 56 to penetrate the same in the stacking direction.

FIGS. 9 to 14 are diagrams for illustrating a method of manufacturing the MEMS sensor shown in FIG. 8.

First, the first electrode 53 consisting of an Al film is formed on the surface of the base layer 52 by sputtering, as shown in FIG. 9.

Then, a sacrificial layer 58 made of SiN is formed on the first electrode 53 by P-CVD, as shown in FIG. 10.

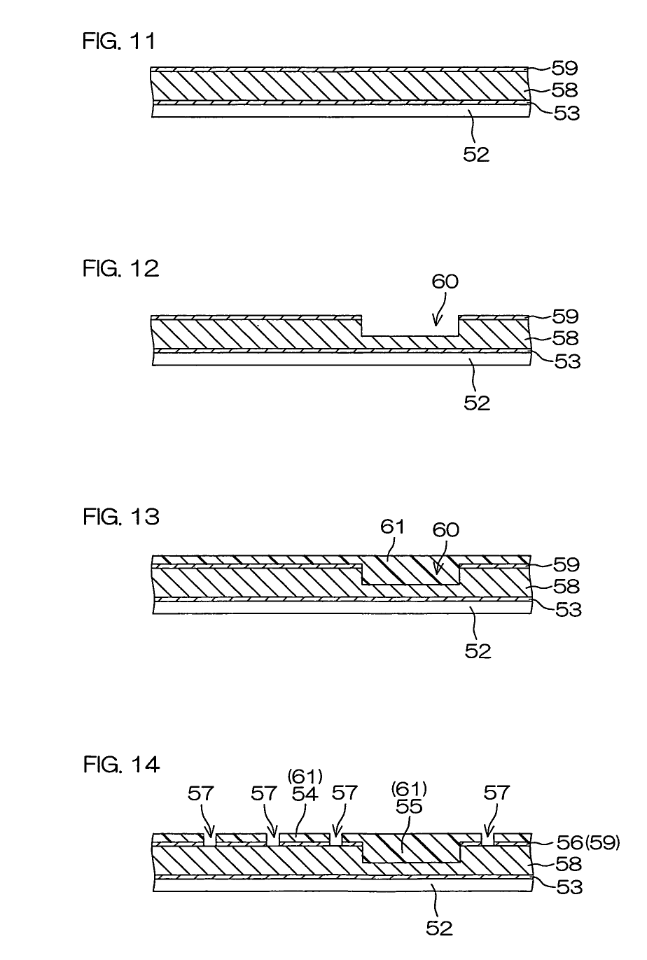

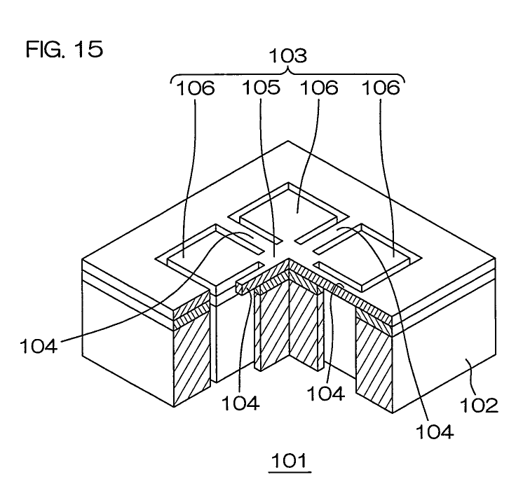

Thereafter an Al film 59 is formed on the sacrificial layer 58 by sputtering, as shown in FIG. 11.

Then, a resist film having an opening in a portion corresponding to a portion for forming the protrusion is formed on the Al film 59. Then, the Al film 59 and the sacrificial layer 58 are etched through the resist film serving as a mask. Consequently, a recess 60 dug from the surface of the Al film 59 up to an intermediate portion of the sacrificial layer 58 is formed, as shown in FIG. 12.

Thereafter the organic material (polyimide, for example) which is the material for the diaphragm 54 and the protrusion 55 is applied onto the overall region of the sacrificial layer 58 having the recess 22, whereby an organic material layer 61 made of the organic material is formed, as shown in FIG. 13. The organic material layer 61 fills up the recess 60 and covers the overall region of the surface of the Al film 59, while the surface thereof is generally planar.

Then, the organic material layer 61 and the Al film are selectively removed, whereby the plurality of through-holes 57 are formed, as shown in FIG. 14. Thus, the organic material layer 61 forms the diaphragm 54 and the protrusion 55, while the Al film 59 forms the second electrode 56. Further, the surface of the sacrificial layer 58 is partially exposed through the through-holes 57. Portions of the sacrificial layer 58 located under the diaphragm 54 and the protrusion 55 are removed by CDE through the through-holes 57. Consequently, the MEMS sensor 51 having the structure shown in FIG. 8 is obtained.

Thus, the MEMS sensor 51 having the structure shown in FIG. 8 can be easily manufactured without etching the base layer 52.

The base layer 52 may not be etched, whereby the MEMS sensor 51 can be loaded on a semiconductor substrate provided with elements such as CMOS devices. In other words, the MEMS sensor 51 can be provided on a common semiconductor substrate mixedly with elements such as CMOS devices.

The MEMS sensor 51 can be used also as an acceleration sensor. When acceleration in the opposed direction of the first electrode 53 and the second electrode 56 is caused in the MEMS sensor 51, the diaphragm 54 is deformed, whereby the second electrode 56 is displaced. The interval between the first electrode 53 and the second electrode 56 changes due to the displacement of the second electrode 56, and the capacitance of the capacitor constituted of the first electrode 53 and the second electrode 56 changes. Therefore, the magnitude of the acceleration caused in the MEMS sensor 51 can be detected on the basis of the change of the capacitance.

While SiN has been illustrated as the material for the sacrificial layer 58, the material for the sacrificial layer 58 is not restricted to SiN, but may simply be a material having an etching selection ratio with the material for the first electrode 53 and the second electrode 56.

While Al has been illustrated as the material for the first electrode 53 and the second electrode 56, a conductive material other than Al such as Cu or doped polysilicon may be employed.

While polyimide has been illustrated as the organic material, polyparaxylene or polyamide may be employed.

The present invention is not restricted to the acceleration sensor and the microphone, but also applicable to a gyro sensor for detecting the angular speed of a substance.

While the present invention has been described in detail by way of the embodiments thereof, it should be understood that these embodiments are merely illustrative of the technical principles of the present invention but not limitative of the invention. The spirit and scope of the present invention are to be limited only by the appended claims.

This application corresponds to Japanese Patent Application No. 2007-131831 filed with the Japan Patent Office on May 17, 2007, the disclosure of which is incorporated herein by reference.

1. A MEMS sensor comprising:
a base layer; and
a deformation portion provided on the base layer at an interval from the base layer and deformed by external force, wherein
the deformation portion is made of an organic material.

2. MEMS sensor according to claim 1, comprising a weight provided on a surface of the deformation portion opposed to the base layer.

3. MEMS sensor according to claim 2, wherein
the weight is made of the organic material, and integrally formed with the deformation portion.

4. MEMS sensor according to claim 3, wherein the organic material is polyimide.

5. MEMS sensor according to claim 2, comprising:
a frame supporting the deformation portion on the periphery of the weight;
a resistive conductor arranged on the deformation portion; and
a wire arranged on the deformation portion and connected to the resistive conductor.

6. MEMS sensor according to claim 1, comprising:
a first electrode provided on a surface of the base layer opposed to the deformation portion; and
a second electrode provided on a surface of the deformation portion opposed to the base layer and opposed to the first electrode at an interval.

7. MEMS sensor according to claim 6, comprising a protrusion provided on the surface of the deformation portion opposed to the base layer.

8. MEMS sensor according to claim 7, wherein
the protrusion is made of the organic material, and integrally formed with the deformation portion.

9. MEMS sensor according to claim 8, wherein
the organic material is polyimide.

10. A method of manufacturing a MEMS sensor, comprising the steps of :
forming a sacrificial layer on a base layer;
forming a recess in the surface of the sacrificial layer;
forming an organic material layer to fill up the recess and to cover the surface of the sacrificial layer;
forming a wire on the organic material layer;
forming a resistive conductor connected with the wire on the organic material layer;
forming a groove along the periphery of the recess in plan view by etching the organic material layer from the surface side of the organic material layer; and
forming a beam and a weight consisting of the organic material layer by etching the sacrificial layer through the groove.

11. A method of manufacturing a MEMS sensor, comprising the steps of:
forming a first electrode made of a first conductive material on a base layer;
forming a sacrificial layer made of a material different from the first conductive material on the first electrode;
forming a second electrode made of a second conductive material identical to or different from the first conductive material on the sacrificial layer;
forming an organic material layer made of an organic material on the second electrode;
forming a through-hole penetrating the organic material layer and the second electrode in the stacking direction thereof; and
forming a space between the first electrode layer and the second electrode by etching the sacrificial layer through the through-hole.
